(19) United States
(12) Patent Application Publication
(10) Pub. No.: US 2009/0321803 A1
(43) Pub. Date: Dec. 31, 2009

(54) Semiconductor device and method of manufacturing the same

(76) Inventors: Jai-Hyun Kim, Yongin-si (KR); Young-Ki Hong, Yongin-si (KR); Ji-Woong Sue, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/457,981

(22) Filed: Jun. 26, 2009

(30) Foreign Application Priority Data
Jun. 30, 2008 (KR) 10-2008-0062546

(51) Int. Cl. H01L 29/68; H01L 21/8239

(52) U.S. Cl. 257/296; 438/396; 257/E29.17; 257/E27.084; 257/E21.645; 438/239

(57) ABSTRACT

A semiconductor device includes a substrate having a cell array region and a peripheral circuit region, a lower structure on the substrate in the cell array region, a first insulation layer on the substrate across the cell array region and the peripheral circuit region, the lower structure being covered with the first insulation layer, a capacitor on the first insulation layer in the cell array region, the capacitor including a lower electrode, a dielectric layer patter, and an upper electrode, a second insulation layer on the first insulation layer, the capacitor being covered with the second insulation layer, a first upper wiring structure on the second insulation layer, the first upper wiring structure being electrically connected to the capacitor and including an upper wiring and a mask pattern, and at least one dummy structure in the peripheral circuit region.

### BACKGROUND

1. Field

Example embodiments relate to a semiconductor device and a method of manufacturing the same. More particularly, example embodiments relate to a semiconductor device including a dummy structure in a peripheral circuit region of a semiconductor substrate and a method of manufacturing the same.

2. Description of the Related Art

Semiconductor memory devices are generally classified as either volatile memory devices or non-volatile memory devices. Volatile memory devices, e.g., dynamic random access memory (DRAM) devices and static random access memory (SRAM) devices, may lose data stored therein when power is shut off. In contrast, non-volatile memory devices, e.g., erasable programmable read-only memory (EPROM) devices, electrically erasable programmable read-only memory (EEPROM) devices and flash memory devices, may maintain data stored therein when power is shut off.

For example, a ferroelectric random access memory (FRAM) device may have operational characteristics of both a volatile memory device, e.g., a readable/writable random access memory (RAM) device, and a non-volatile memory device, e.g., a read-only memory (ROM) device. Data stored in the FRAM device may be maintained sufficiently for a long time even when applied power is shut off because of the spontaneous polarization of ferroelectrics, and thus the FRAM device may have excellent data preservation characteristics. For these reasons, the FRAM device may be widely used for memory devices of which the principal function is more for data preservation rather than for repeated reading/writing of data. For example, the FRAM device may be advantageously used for an arithmetic unit that does not need frequent reading/writing of data in a memory device for storing a program and so on.

According to a conventional method of manufacturing the FRAM device, capacitors may be formed in a cell array region of a substrate, and an insulation layer may be formed on the substrate in such a manner that a gap space between neighboring capacitors is filled with the insulation layer. However, the insulation layer may be formed non-uniformly in accordance with positions thereof on the substrate. The non-uniform insulation layer may exert non-uniform stress on the substrate, so the insulation layer may cause, e.g., great stress at a boundary region of the cell array region and a peripheral circuit region of the substrate due to the non-uniformity of the insulation layer between the cell array region and the peripheral circuit region.

Accordingly, when an electric wiring for transferring electrical signals to the capacitor is connected to the capacitor through the insulation layer, cracks may be generated between the capacitor and the wiring due to the great stress of the insulation layer. For example, a great stress may be applied to, e.g., concentrated at, a boundary surface of the cell array region and the peripheral circuit region during the node separation of the capacitors, and thus excessive stress may cause cracks between the capacitor and the wiring due to the great stress of the insulation layer. Such cracks may separate the wiring and the capacitor from each other, i.e., a lifting failure between the wirings and the capacitors, thereby deteriorating electrical characteristics and reliability of the FRAM device.

### SUMMARY

Embodiments are therefore directed to a semiconductor device and a method of manufacturing the same, which substantially overcome one or more of the problems due to the limitations and disadvantages of the related art.

It is therefore a feature of an embodiment to provide a semiconductor device having at least one dummy structure in a peripheral circuit region to improve the electrical characteristics and operational reliability of the semiconductor device.

It is therefore another feature of an embodiment to provide a method of manufacturing a semiconductor device having at least one dummy structure in a peripheral circuit region to thereby improve the electrical characteristics and operational reliability of the semiconductor device.

At least one of the above and other features and advantages may be realized by providing a semiconductor device, including a substrate having a cell array region and a peripheral circuit region. The device may include a lower structure in the cell array region, a first insulation layer in the cell array region and the peripheral circuit region, a capacitor on the first insulation layer in the cell array region, a second insulation layer on the first insulation layer to cover the capacitor, an upper wiring structure on the second insulation layer and at least one dummy structure formed in the peripheral circuit region. The capacitor may include a lower electrode, a dielectric layer pattern and an upper electrode, and the upper wiring structure may be electrically connected to the capacitor and include an upper wiring and a mask pattern.

In an example embodiment, the dummy structure may be positioned on the first insulation layer and may have substantially the same structure as the capacitor. The dummy structure may include a dummy lower electrode, a dummy dielectric layer pattern and a dummy upper electrode. A blocking layer pattern may be further formed on a sidewall of at least one of the capacitor and the dummy structure.

In an example embodiment, the dummy structure may be formed on the second insulation layer and may have substantially the same structure as the upper wiring structure. For example, the dummy structure may include a dummy conductive layer pattern and a dummy mask pattern.

In an example embodiment, a first dummy structure may be positioned on the first insulation layer and a second dummy structure may be positioned on the second insulation layer. The first and the second dummy structures may have substantially the same height as that of the capacitor and the upper wiring structure, respectively. Further, the second dummy structure may make contact with the first dummy structure.

In an example embodiment, a third insulation layer, which may cover the upper wiring structure, and an additional upper wiring structure, which may be positioned on the third insulation layer and may be electrically connected to the upper wiring structure, may be further positioned on the substrate.

At least one of the above and other features and advantages may also be realized by providing a method of manufacturing a semiconductor device. A lower structure may be formed in a cell array region of a substrate including the cell array region and a peripheral circuit region. A first insulation layer may be formed on the substrate across the cell array region and the peripheral circuit region, so that the lower structure in the cell array region may be covered with the first insulation layer. A capacitor may be formed on the first insulation layer in the cell array region, and a second insulation layer may be formed on the first insulation layer. Therefore, the capacitor may be covered with the second insulation layer. An upper wiring structure may be formed on the second insulation layer in such a manner that the upper wiring structure may be electrically connected to the capacitor. At least one dummy structure may be formed in the peripheral circuit region.

In an example embodiment, a blocking layer pattern may be further formed on a sidewall of the capacitor.

In an example embodiment, the upper wiring structure and the dummy structure are formed as follows. A conductive layer may be formed on the second insulation layer. A mask pattern and a dummy mask pattern may be simultaneously formed on the conductive layer in the cell array region and in the peripheral circuit region. The conductive layer may be etched to form an upper conductive layer pattern under the mask pattern and form a dummy conductive layer under the dummy mask pattern.

In an example embodiment, the capacitor and the dummy structure may be formed as follows. A lower electrode layer may be formed on the first insulation layer and a dielectric layer may be formed on the lower electrode layer. An upper electrode layer may be formed on the dielectric layer. Then, the upper electrode layer, the dielectric layer and the lower electrode layer may be patterned into the capacitor in the cell array region and the dummy structure in the peripheral circuit region. The capacitor may include a lower electrode, a dielectric layer pattern and an upper electrode that are stacked in the cell array region of the substrate and the dummy structure may include a dummy lower electrode, a dummy dielectric layer pattern and a dummy upper electrode that are stacked on the peripheral circuit region of the substrate. A blocking layer pattern may further be formed on a sidewall of the capacitor and the dummy structure, respectively.

In an example embodiment, the capacitor and at least one dummy structure may be formed as follows. A lower electrode layer may be formed on the first insulation layer and a dielectric layer may be formed on the lower electrode layer. Then, an upper electrode layer may be formed on the dielectric layer. Then, the upper electrode layer, the dielectric layer and the lower electrode layer are patterned into the capacitor and the dummy structure in the cell array region and the peripheral circuit region, respectively. The capacitor may include a lower electrode, a dielectric layer pattern and an upper electrode that may be stacked in the cell array region of the substrate and the first dummy structure may include a dummy lower electrode, a dummy dielectric layer pattern and a dummy upper electrode that are stacked on the peripheral circuit region of the substrate. Further, the upper wiring structure and at least one dummy structure may be formed as follows. A conductive layer may be formed on the second insulation layer and a mask layer may be formed on the conductive layer. Then, the mask layer and the conductive layer may be patterned to form a first upper wiring structure including a conductive layer pattern and a mask pattern in the cell array region and a second dummy structure including a dummy conductive pattern and a dummy mask pattern in the peripheral circuit region.

In an example embodiment, a third insulation layer may be further formed on the second insulation layer such that the upper wiring structure may be covered with the third insulation layer and a second upper wiring structure may be formed on the third insulation layer such that the second upper wiring structure may be electrically connected to the upper wiring structure.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 to 5 illustrate cross-sectional views of stages in a method of manufacturing a semiconductor device in accordance with an example embodiment;

FIG. 6 illustrates a cross-sectional view of a method of manufacturing a semiconductor memory device according to another example embodiment;

FIG. 7 illustrates a cross-sectional view of a method of manufacturing a semiconductor memory device according to another example embodiment;

FIGS. 8 and 9 illustrate cross-sectional views of a method of manufacturing a semiconductor device according to another example embodiment;

FIG. 10 illustrates a graph of a polarization degree distribution in a semiconductor device including a dummy structure formed in a peripheral circuit region in accordance with an example embodiment; and

FIG. 11 illustrates a graph of a polarization degree distribution in a conventional semiconductor device not including a dummy structure in a peripheral circuit region.

### DETAILED DESCRIPTION

Korean Patent Application No. 10-2008-0062546, filed on Jun. 30, 2008, in the Korean Intellectual Property Office (KIPO), and entitled: “Semiconductor Device and Method of Manufacturing the Same,” is incorporated by reference herein in its entirety.

Various example embodiments will be described more fully hereinafter with reference to the accompanying drawings, in which example embodiments are shown. The present invention may, however, be embodied in many different forms and should not be construed as limited to example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Similarly, it will also be understood that when a layer is referred to as being “between” two layers, it can be the only layer between the two layers, or one or more intervening layers may also be present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have substantially the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

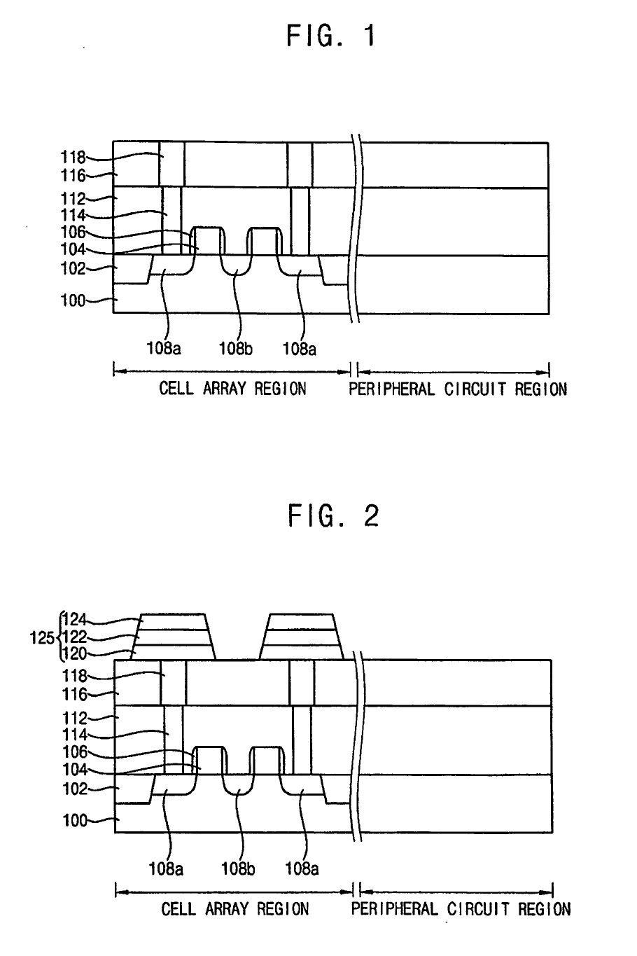

FIGS. 1 to 5 illustrate cross-sectional views of stages in a method of manufacturing a semiconductor device in accordance with an example embodiment. While the example embodiment in FIGS. 1-5 illustrates a method of manufacturing a non-volatile memory device, e.g., a ferroelectric random access memory (FRAM) device, any other semiconductor devices such as a volatile memory device, e.g., a dynamic random access memory (DRAM) device, may also be manufactured under the same characteristics and advantages, as would be known to one of ordinary skill in the art.

Referring to FIG. 1, a substrate 100 including a cell array region and a peripheral circuit region may be prepared, e.g., the peripheral circuit region may be around the cell array region. The substrate 100 may include, e.g., one or more of a silicon (Si) substrate, a germanium (Ge) substrate, a silicon-on-insulator (SOI) substrate, a germanium-on-insulator (GOI) substrate, etc.

In example embodiments, a bit line and a word line for reading/writing data may be formed in the cell array region of the substrate 100. Circuit devices may be arranged on the peripheral circuit region of the substrate 100 and may be electrically connected to the word line and the bit line in the cell array region of the substrate 100, to thereby drive and control conductive devices in the cell array region.

An insulation layer 102 may be formed on a portion of the substrate 100 by an isolation process, to thereby define an active region on the substrate 100. A plurality of conductive devices may be formed on the active region, and the insulation layer 102 may insulate the plurality of conductive devices on the active region from conductive devices on neighboring active regions. For that reason, the insulation layer 102 may hereinafter be referred to as a device isolation layer 102. For example, the isolation process for forming the device isolation layer 102 may include a shallow-trench isolation (STI) process and a thermal oxidation process. For example, the device isolation layer 102 may include silicon oxide, e.g., one or more of undoped silicate glass (USG), spin-on glass (SOG), flowable oxide (FOₓ), tetraethyl orthosilicate (TEOS), plasma-enhanced TEOS (PE-TEOS) and high-density plasma chemical vapor deposition (HDP-CVD) oxide.

A gate structure 104 may be formed on the active region of the substrate 100. In an example embodiment, the gate structure 104 may include a gate insulation layer pattern (not shown), a gate electrode (not shown), and a gate mask (not shown) that may be stacked in the order named on the active region of the substrate 100. The gate insulation layer pattern may include, e.g., silicon oxide and/or metal oxide, and the gate electrode may include, e.g., doped polysilicon, metal, metal nitride and/or metal silicide. The gate mask may include, e.g., silicon nitride and/or silicon oxynitride.

A gate spacer 106 may be formed on a sidewall of the gate structure 104 and may include, e.g., silicon nitride and/or silicon oxynitride.

An ion implantation process may be performed on the active region of the substrate 100 using the gate structure 104 and the gate spacer 106 as a mask, to thereby form first and second impurity regions 108a and 108b at a surface portion of the substrate 100 adjacent to the gate structure 104. The first and second impurity regions 108a and 108b may function as source and drain regions of a cell transistor on the active region, respectively. A plurality of the active regions may be arranged to extend in a first direction on the substrate 100, e.g., each active region may be defined between two adjacent device isolation layers 102, and the gate structure 104 may extend in a second direction, e.g., a direction substantially perpendicular to the first direction. The second impurity region 108b may be electrically connected to a bit line, which may be described in detail hereinafter, and the first impurity region 108a may be electrically connected to a lower electrode 120 of a capacitor 125. According to example embodiments, the second impurity region 108b may be formed at the surface portion of the active region between adjacent gate structures 104 and may be referred to as a common drain region. The first impurity region 108a may be formed at the surface portion of the active region which is opposite to the common drain region with respect to the gate structure 104 and may be referred to as a source region.

A lower structure, e.g., a cell transistor, may be formed on the active region of the substrate 100 by the formation of the gate structure 104 and the first and the second impurity regions 108a and 108b. Thus, the cell transistor in the present example embodiment may include the gate structure 104, the gate spacer 106, the first impurity region 108a, and the second impurity region 108b. A string of the gate structures 104 of adjacent cell transistors may function as a word line of the semiconductor device.

Referring again to FIG. 1, a first insulation layer 112 may be formed on the substrate 100, e.g., to cover the cell region and the circuit peripheral region, to a thickness sufficient to cover the cell transistors. The first insulation layer 112 may be formed, e.g., by a chemical vapor deposition (CVD) process, a plasma-enhanced chemical vapor deposition (PECVD) process, a spin-coating process, an HDP-CVD process, etc. For example, the first insulation layer 112 may include, e.g., one or more of phosphosilicate glass (PSG), borophosphosilicate glass (BPSG), TEOS, PE-TEOS, USG, SOG, FOₓ, HDP-CVD oxide, etc. These may be used alone or in combinations thereof.

Thereafter, an upper portion of the first insulation layer 112 may be planarized, e.g., by a polishing process. For example, a chemical mechanical polishing (CMP) process and/or an etch-back process may be used for planarizing the upper portion of the first insulation layer 112.

Then, the first insulation layer 112 may be partially removed from the substrate 100 to form a first contact hole (not shown) through which the first impurity region 108a may be exposed. For example, a photolithography process may be used for removing a portion of the first insulation layer 112, i.e., for forming the first contact hole.

A first conductive layer (not shown) may be formed on the first insulation layer 112 to a sufficient thickness to fill, e.g., completely fill, the first contact hole by, e.g., a sputtering process, a CVD process, a low-pressure chemical vapor deposition (LPCVD) process, an atomic layer deposition (ALD) process, a pulsed laser deposition (PLD) process, a vacuum deposition process, etc. The first conductive layer may include, e.g., one or more of doped polysilicon, a metal and/or a metal compound. Examples of the metal and/or metal compound may include one or more of tungsten (W), tungsten nitride (WNₓ), titanium (Ti), titanium nitride (TiNₓ), aluminum (Al), aluminum nitride (AlNₓ), titanium aluminum nitride (TiAlNₓ), tantalum (Ta), tantalum nitride (TaNₓ), etc. These may be used alone or in combinations thereof.

Thereafter, an upper portion of the first conductive layer may be removed from the first insulation layer 112 until the first insulation layer 112 is exposed, i.e., the first conductive layer may remain only in the first contact hole, to form a first contact 114 in the first contact hole. Therefore, the first contact 114 may make contact with the first impurity region 108a. For example, the first conductive layer may be removed from the first insulation layer 112 by a CMP and/or an etch-back process.

According to example embodiments, a bit line contact hole (not shown) may be formed through the first insulation layer 112 simultaneously with the first contact hole, and thus the second impurity region 108b may be exposed through the bit line contact hole. In case that both the first contact hole and the bit line contact hole are formed through the first insulation layer 112, a bit line contact (not shown) may be formed in the bit line contact hole at a substantially same time, i.e., simultaneously, as the first contact is formed in the first contact hole. The bit line contact may make contact with the second impurity region 108b, while the first contact 114 may make contact with the first impurity region 108a. Further, a bit line structure (not shown) may be formed on the first insulation layer 112 and may make electrical contact with the bit line contact. For example, the bit line structure may include a bit line (not shown) and a bit line mask (not shown) that may be stacked in the order named on the first insulation layer 112. The bit line may include, e.g., doped polysilicon, metal, metal nitride and/or fire-resistant metal silicide, and the bit line mask may include, e.g., silicon nitride and/or silicon oxynitride. The bit line may extend in a direction perpendicular to that of the word line. In addition, a bit line spacer (not shown) may be formed on a sidewall of the bit line structure. In an example embodiment, the bit line spacer may include, e.g., silicon nitride and/or silicon oxynitride.

Referring again to FIG. 1, a second insulation layer 116 may be formed, e.g., to cover the cell region and the circuit peripheral region, on the first insulation layer 112 through which the first contact 114 and the bit line contact are formed, and thus the first contact 114 and the bit line contact may be covered with the second insulation layer 116. For example, the second insulation layer 116 may include an oxide, e.g., a silicon oxide. The second insulation layer 116 may be formed by, e.g., a CVD process, a PECVD process, a spin-coating process, an HDP-CVD process, etc. The second insulation layer 116 may include, e.g., one or more of BPSG, PSG, SOG, USG, FOₓ, TEOS, PE-TEOS, HDP-CVD oxide, and so on. These may be used alone or in combinations thereof.

The second insulation layer 116 may be partially removed from the first insulation layer 112, to form a second contact hole (not shown) through which the first contact 114 may be exposed. In the present example embodiment, the second insulation layer 116 may be removed, e.g., by an anisotropic etching process, and the second contact hole may have a width substantially larger than that of the first contact 114.

A second conductive layer (not shown) may be formed on the second insulation layer 116 to a sufficient thickness to fill, e.g., to completely fill, the second contact hole. The second conductive layer may be formed, e.g., by a sputtering process, a CVD process, an ALD process, a vacuum deposition process, a PLD process, etc., and may include, e.g., one or more of doped polysilicon, metal and/or metal nitride. Examples of the metal and the metal nitride may include, e.g., one or more of tungsten (W), titanium (Ti), aluminum (Al), tantalum (Ta), copper (Cu), tungsten nitride (WNₓ), titanium nitride (TiNₓ), aluminum nitride (AlNₓ), titanium aluminum nitride (TiAlNₓ), tantalum nitride (TaNₓ), etc. These may be used alone or in combinations thereof. In example embodiments, the second conductive layer may be formed into a single layer including a metal layer or a metal nitride layer. Otherwise, the second conductive layer may also be formed into a multilayer structure including at least one metal layer and at least one metal nitride layer.

Then, an upper portion of the second conductive layer may be removed from the second insulation layer 116, e.g., by a CMP or an etch-back process, until the second insulation layer 116 is exposed. Therefore, the second conductive layer may merely remain in the second contact hole to form a second contact 118 making contact with the first contact 114.

Referring to FIG. 2, a lower electrode layer (not shown), a dielectric layer (not shown), and an upper electrode layer (not shown) may be sequentially formed on the second insulation layer 116 through which the second contact 118 is formed. The second contact 118 may be covered with the lower electrode layer.

In example embodiments, the lower electrode layer may include a first lower electrode layer on the second insulation layer 116 and a second lower electrode layer on the first lower electrode layer.

The first lower electrode layer may be formed, e.g., by using an electron beam deposition process, a sputtering process, a CVD process, a PLD process, an ALD process, etc., and may include, e.g., a metal compound. Examples of the metal compound may include, e.g., one or more of titanium aluminum nitride (TiAlNₓ), titanium nitride (TiNₓ), titanium silicon nitride (TiSiNₓ), tantalum nitride (TaNₓ), tungsten nitride (WNₓ), tantalum silicon nitride (TaSiNₓ), etc. These may be used alone or in combinations thereof. In the present example embodiment, the first lower electrode layer may be formed on, e.g., directly on, the second insulation layer 116 to a thickness of about 10 nm to about 50 nm.

The second lower electrode layer may be formed on the first lower electrode, e.g., by a CVD process, an ALD process, an electron beam deposition process, a PLD process, an ALD process, etc., and may include a metal, an alloy and/or a metal oxide. Examples of the metal, the alloy and the metal oxide may include, e.g., one or more of iridium (Ir), platinum (Pt), ruthenium (Ru), palladium (Pd), gold (Au), an iridium ruthenium alloy, iridium oxide (IrOₓ), strontium ruthenium oxide (SrRuOₓ), calcium nickel oxide (CaNiOₓ), calcium ruthenium oxide (CaRuOₓ), etc. These may be used alone or in combinations thereof. In the present example embodiment, the second lower electrode layer may be formed on, e.g., directly on, the first lower electrode layer to a thickness of about 10 nm to about 200 nm.

The dielectric layer may include a ferroelectric material or a metal-doped ferroelectric material. Examples of the ferroelectric material may include, e.g., one or more of lead zirconium titanate [(Pb, Zr)TiO₃; PZT], strontium bismuth tantalate (SrBi₂Ta₂O₉; SBT), bismuth lanthanum titanate [(Bi, La)TiO₃; BLT], lead lanthanum zirconium titanate [(Pb(La, Zr)TiO₃); PLZT], bismuth strontium titanate [(Bi, Sr)TiO₃; BST], etc. These may be used alone or in combinations thereof. Examples of the metal doped into the ferroelectric material may include, e.g., one or more of copper (Cu), lead (Pb), bismuth (Bi), etc. For example, the PZT may be deposited onto the second lower electrode layer by a metal organic chemical vapor deposition (MOCVD) process to form the dielectric layer on, e.g., directly on, the second lower electrode layer to a thickness of about 10 nm to about 200 nm. In such a case, the atomic weight ratio of lead (Pb), zirconium (Zr), titanium (Ti) and oxygen (O) in the PZT may be in a range of about 1.0:0.2:0.8:3.0 to about 1.0:0.5:0.5:3.0.

According to example embodiments, the upper electrode layer may include a first upper electrode layer on the dielectric layer and a second electrode layer on the first upper electrode layer. A metal oxide may be deposited onto the dielectric layer by a deposition process to form the first upper electrode layer. The deposition process may include, e.g., an electron beam deposition process, a sputtering process, a CVD process, an ALD process, a PLD process, etc. Examples of the metal oxide may include, e.g., one or more of strontium ruthenium oxide (SrRuOₓ), strontium titanium oxide (SrTiOₓ), lanthanum nickel oxide (LaNiOₓ), calcium ruthenium oxide (CaRuOₓ), etc. These may be used alone or in combinations thereof. The first upper electrode layer may be formed on, e.g., directly on, the dielectric layer to a thickness of about 1 nm to about 200 nm.

A metal, an alloy, and/or a metal oxide may be deposited onto the first upper electrode layer by a deposition process to form the second upper electrode layer on the first upper electrode layer. The deposition process may include, e.g., an electron beam deposition process, a sputtering process, a CVD process, an ALD process, a PLD process, etc., and examples of the metal, alloy and/or a metal oxide may include one or more of iridium (Ir), platinum (Pt), ruthenium (Ru), palladium (Pd), gold (Au), an iridium ruthenium alloy, iridium oxide (IrOₓ), strontium ruthenium oxide (SrRuOₓ), calcium nickel oxide (CaNiOₓ), calcium ruthenium oxide (CaRuOₓ), etc. These may be used alone or in combinations thereof. The second upper electrode layer may be formed on, e.g., directly on, the first upper electrode layer to a thickness of about 10 nm to about 200 nm.

A hard mask (not shown) or a photoresist pattern (not shown) may be formed on the second upper electrode layer, and then the upper electrode layer, the dielectric layer, and the lower electrode layer may be sequentially and partially removed from the second insulation layer 116 by an etching process using the hard mask or the photoresist pattern as an etching mask to form a capacitor 125 including a lower electrode 120, a dielectric layer pattern 122, and an upper electrode 124 in the cell array region on the second insulation layer 116 including the second contact 118. For example, the lower electrode 120 may include a first lower electrode layer pattern and a second lower electrode layer pattern, and the upper electrode 124 may include a first upper electrode layer pattern and a second upper electrode layer pattern.

In example embodiments, the etching process for forming the upper electrode 124, the dielectric layer pattern 122, and the lower electrode 120 may include a plasma etching process using a reaction gas, e.g., argon (Ar) gas, carbon tetrafluoride (CF₄) gas, trifluoromethane (CHF₃) gas, and carbon tetrachloride (CCl₄) gas. The lower electrode 120 of the capacitor 125 may be electrically connected to the first impurity region 108a through the second contact 118 and the first contact 114.

According to other example embodiments, a connecting pad (not shown) may be additionally formed between the lower electrode 120 of the capacitor 125 and the second contact 118. The connecting pad may have an area substantially larger than that of the second contact 118, and thus the lower electrode 120 may make contact with the connecting pad much more easily than with the second contact 118, thereby increasing electrical contact reliability of the lower electrode 120 with the first impurity region 108a. For example, the connecting pad may include doped polysilicon, a metal, and/or a metal compound.

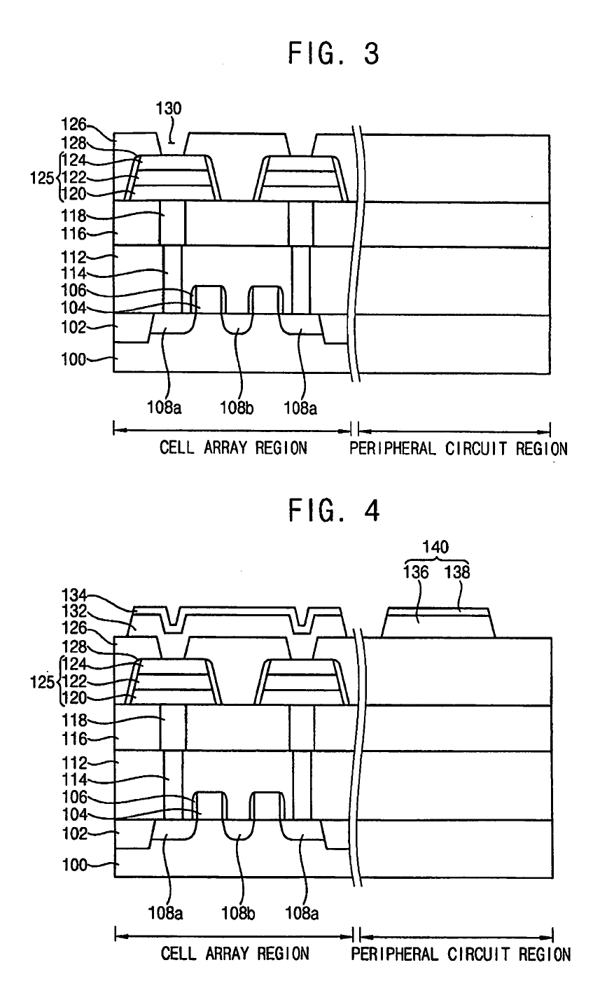

Referring to FIG. 3, a third insulation layer 126 may be formed, e.g., to cover the cell region and the circuit peripheral region, on the second insulation layer 116 on which the capacitor 125 is formed. The third insulation layer 126 may be formed to a sufficient thickness to cover the capacitor 125, e.g., a top surface of the capacitor 125 may be covered with the third insulation layer 126. In this respect, it is noted that a “top surface” of any element hereinafter refers to a surface facing away from the substrate 100. In an example embodiment, the third insulation layer 126 may be formed by various deposition processes and may include silicon oxide. For example, the deposition process for forming the third insulation layer 126 may include a CVD process, a PECVD process, a spin-coating process, an HDP-CVD process, etc. Examples of the silicon oxide may include one or more of BPSG, PSG, USG, SOG, FOₓ, TEOS, TEOS deposited by the PECVD process and oxide deposited by the HDP-CVD process. For example, the composition of the third insulation layer 126 may be the substantially the same as or substantially similar to that of the second insulation layer 116 and/or the first insulation layer 112. In another example, the composition of the first, second, and third insulation layers 112, 116, and 126 may be different from one another.

As illustrated in FIG. 3, a blocking layer pattern 128 may be formed on a sidewall of the capacitor 125, e.g., the blocking layer 128 may be formed between the capacitor 125 and the third insulating layer 126. For example, the blocking layer pattern 128 may completely cover sidewalls, i.e., surfaces facing the third insulating layer 126 and extending between top and bottom surfaces of the capacitor 125, of the lower electrode 120, the dielectric layer 122, and the upper electrode 124. For example, the blocking layer pattern 128 may include metal oxide and/or metal nitride. Examples of the metal oxide and metal nitride may include one or more of titanium oxide (TiOₓ), aluminum oxide (AlOₓ), silicon nitride (Si₃N₄), etc. These may be used alone or in combinations thereof. If the blocking layer pattern 128 is not formed on the sidewall of the capacitor 125, hydrogen atoms may penetrate into the capacitor 125 in subsequent processes, and thus oxygen atoms in the dielectric layer patterns 122 may react with the hydrogen atoms to generate oxygen vacancies in the dielectric layer pattern 122. The oxygen vacancies may deteriorate polarization characteristics of the dielectric layer pattern 122, thereby causing operational failure of the capacitor 125, which in turn, may reduce the operational reliability of a semiconductor device including the capacitor 125. In an example embodiment, the blocking layer pattern 128 may be formed on the sidewall of the capacitor 125, and thus the capacitor 125 may be sufficiently protected from environments, e.g., diffusion or chemical interaction, in subsequent processes. Accordingly, hydrogen atoms may be sufficiently prevented from penetrating into the capacitor 125 in the subsequent processes, and thus the oxygen vacancies in the capacitor 125 may be eliminated or substantially minimized by the blocking layer pattern 128 in order to improve the operational reliability of the semiconductor device.

As illustrated in FIG. 3, the capacitor 125 may be formed in the cell array region of the substrate 100, while no capacitors are formed in the peripheral circuit region of the substrate 100. Thus, since the third insulation layer 126 is formed to cover the cell region and the circuit peripheral region of the substrate 100, a structure, e.g., thickness, of the third insulation layer 126 may be non-uniform across the cell array region and the peripheral circuit region of the substrate 100. Therefore, a density, e.g., dislocation density, of the third insulation layer 126 may be non-uniform across the cell array region and the peripheral circuit region of the substrate 100. Particularly, a density of the third insulation layer 126 may be most clearly changed at a boundary region of the cell array region and the peripheral circuit region of the substrate 100.

Portions of the third insulation layer 126 may be removed by an etching process, e.g., an anisotropic etching process, to form a first opening 130 exposing a portion of the upper electrode 124 of the capacitor 125. For example, a sidewall of the first opening 130 may be inclined at an angle with respect to the substrate 100 in such a manner that an upper portion of the first opening 130 may have a width larger than that of a lower portion of the first opening 130. For example, the first opening 130 may have an inverted trapezoidal cross section, so a shorter base of the trapezoidal cross-section may extend directly on the upper electrode 124 of the capacitor 125.

Referring to FIG. 4, a third conductive layer (not shown) may be formed on the third insulation layer 126 to a sufficient thickness to fill, e.g., completely fill, the first opening 130. In an example embodiment, a metal, a conductive metal oxide compound, and/or a metal nitride compound may be deposited onto the third insulation layer 126 by a deposition process to form the third conductive layer on the third insulation layer 126. Examples of the metal, metal oxide, and the metal nitride may include one or more of titanium aluminum nitride (TiAlNₓ), titanium (Ti), titanium nitride (TiNₓ), iridium (Ir), iridium oxide (IrOₓ), platinum (Pt), ruthenium (Ru), ruthenium oxide (RuOₓ), aluminum (Al), and so on. These may be used alone or in combinations thereof. The deposition process may include, e.g., a sputtering process, a CVD process, an ALD process, a PLD process, a vacuum deposition process, etc.

In example embodiments, the third conductive layer may be formed on the entire substrate 100 across the cell array region and the peripheral circuit region. That is, both the cell array region and the peripheral circuit region of the substrate 100 may be covered with the third conductive layer, e.g., both the cell array region and the peripheral circuit region may be covered simultaneously with a same layer. Since the third insulation layer 126 may be non-uniform, i.e., may have a density difference between the cell array region and the peripheral circuit region of the substrate 100, the third conductive layer on the third insulation layer 126 may also be non-uniform across the cell array and peripheral circuit regions of the substrate 100. In other words, a structure of the third conductive layer may correspond to the structure of the third insulating layer 126, so a density of the third conductive layer may also be changed at the boundary region of the cell array and peripheral circuit regions of the substrate 100.

A mask layer (not shown) may be formed on the third conductive layer, e.g., on the entire third conductive layer, and may be patterned, e.g., simultaneously, into a mask pattern 134 in the cell array region of the substrate 100 and into a dummy mask pattern 138 on the peripheral circuit region of the substrate 100. The mask pattern 134 and the dummy mask pattern 138 may include nitride, e.g., silicon nitride, and oxynitride, e.g., silicon oxynitride, respectively. Hereinafter, the third conductive layer in the cell array region may be referred to as a first portion of the third conductive layer and the third conductive layer in the peripheral circuit region may be referred to as a second portion of the third conductive layer.

The first portion of the third conductive layer may be formed into a first upper wiring 132 in the cell array region by an etching process using the mask pattern 134 as an etching mask, and the second portion of the third conductive layer may be formed into a dummy conductive pattern 136 in the peripheral circuit region by an etching process using the dummy mask pattern 138 as an etching mask. That is, the first and the second portions of the third conductive layer may be patterned, e.g., simultaneously, into the first upper wiring 132 and the dummy conductive pattern 136, respectively. The first upper wiring 132 may be formed on the third insulation layer 126 in the cell array region of the substrate 100, in such a manner that the first opening 130 may be filled, e.g., completely filled, with the first upper wiring 132. The dummy conductive pattern 136 may be formed on the third insulation layer 126 in the peripheral circuit region of the substrate 100.

Accordingly, a dummy structure 140, including the dummy conductive pattern 136 and dummy mask pattern 138, may be formed on the third insulation layer 126 in the peripheral circuit region, and a first upper wiring structure, including the first upper wiring 132 and the mask pattern 134, may be formed on the third insulation layer 126 in the cell array region. Formation of the dummy structure 140 may compensate for the density difference in the third insulation layer 126 between the cell array region and the peripheral circuit region of the substrate 100, as will be discussed in more detail below. The dummy conductive pattern 136 and the dummy mask pattern 138 of the dummy structure 140 may be sequentially formed on the third insulation layer 126 in the peripheral circuit region of the substrate 100. The dummy structure 140 may have any suitable shape, e.g., the dummy structure 140 may have a trapezoidal cross-section as illustrated in FIG. 4.

According to example embodiments, the first upper wiring structure may include the first upper wiring 132 and the mask pattern 134 on the third insulation layer 126 in the cell array region of the substrate 100. The first upper wiring 132 may be electrically connected to the capacitor 125, e.g., the first upper wiring 132 may directly contact adjacent capacitors 125 through the first openings 130 thereof. The first upper wiring structure may be formed by implementing a substantially same process used for forming the dummy structure 140. The first upper wiring structure and the dummy structure 140 may be spaced apart from each other along a horizontal direction, i.e., a direction parallel to a direction of a word line. The first upper wiring structure and the dummy structure 140 may have same or different cross-sections, and may have a substantially same height, i.e., a distance as measured along a direction normal to the substrate 100. In other words, a top surface of the first upper wiring structure and a top surface of the dummy structure 140 may be positioned at a substantially same height, i.e., at a substantially same distance from a top surface of the second insulation layer 116 as measured along a direction normal to the substrate 100.

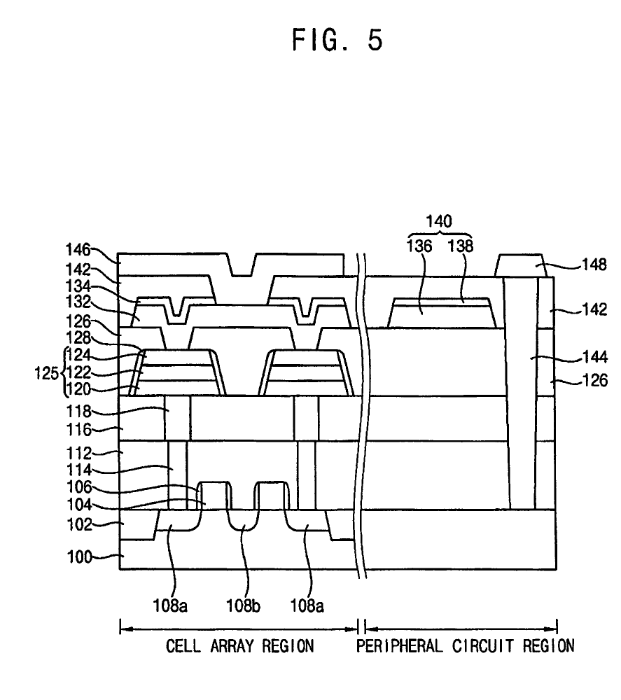

Therefore, since the heights of the first upper wiring structure and the dummy structure 140 may be substantially equal to each other, i.e., may have substantially coplanar top surfaces, the density of the patterns may be kept substantially uniform throughout the entire region of the substrate 100. As such, when a fourth insulation layer 142 (refer to FIG. 5) is formed subsequently on the third insulation layer 126, the fourth insulation layer 142 may cover structures on the third insulation layer 126 that extend to a substantially same height, i.e., the first upper wiring structure and the dummy structure 140. Therefore, density variation between the cell array region and the peripheral circuit region in the fourth insulation layer 142 may be substantially minimized. When the density variation in the fourth insulation layer 142 is minimized, i.e., increased density uniformity in the fourth insulation layer 142, an internal stress in the fourth insulation layer 142 caused by a density difference may be substantially reduced. A reduced internal stress in the fourth insulation layer 142 may minimize stress on the third insulation layer 126 and on the capacitor 125, so cracks on a boundary surface between the first upper wiring 132 and the capacitor 125 may be prevented or substantially minimized. In other words, a reduced internal stress in the fourth insulation layer 146 may prevent or substantially minimize a lifting failure phenomenon between the first upper wiring 132 and the capacitor 125, so electrical characteristics and operational reliability of the semiconductor device including the capacitor 125 may be improved.

Referring to FIG. 5, the fourth insulation layer 142 may be formed on the third insulation layer 126 to cover the first upper wiring 132, the mask pattern 134, and the dummy structure 140. For example, the fourth insulation layer 142 may be on, e.g., directly on, the dummy structure 140, so the dummy structure 140 may be completely enclosed between the third and fourth insulation layers 126 and 142. The fourth insulation layer 142 may be formed using silicon oxide, e.g., BPSG, PSG, SOG, USG, FOₓ, TEOS, PE-TEOS, HDP-CVD oxide, etc. The fourth insulation layer 142 may be formed on the third insulation layer 126 by using, e.g., a CVD process, a spin-coating process, a PECVD process, a HDP-CVD process, etc. The fourth insulation layer 142 may be formed using substantially the same or similar oxide applied for forming the third insulation layer 126, the second insulation layer 116, and/or the first insulation layer 112, or may be formed using a different oxide.

As described above, the dummy structure 140 may be disposed in the peripheral circuit region of the substrate 100 and may sufficiently compensate for the density difference of the third insulation layer 126 between the cell array region and the peripheral circuit region. Therefore, internal stress and density variation in the fourth insulation layer 142 formed on the third insulation layer 126 may be prevented or substantially minimized.

The fourth insulation layer 142 and the mask pattern 134 in the cell array region of the substrate 100 may be partially etched to form a second opening (not shown) exposing the first upper wiring 132. The fourth insulation layer 142, the third insulation layer 126, the second insulation layer 116 and the first insulation layer 112 in the peripheral circuit region of the substrate 100 may be partially removed in the same etching process for forming the second opening, to thereby form a third opening (not shown) exposing a contact area of the substrate 100. That is, the fourth insulation layer 142 and the mask pattern 134 may be partially etched to form the second opening in the cell array region, while the first insulation layer 112 to the fourth insulation layer 142 may be, e.g., subsequently or simultaneously to formation of the second opening, etched to form the third opening exposing the contact region in the peripheral circuit region of the substrate 100.

Thereafter, a fourth conductive layer (not shown) may be formed on the fourth insulation layer 142 to a sufficient thickness to fill up the second and third openings. Then, the fourth conductive layer may be patterned to form a first plug filling the second opening and a second plug 144 filling the third opening. The first plug may be dented, and the second plug 144 may have a planar upper surface. The first plug may be used as a wiring, and the second plug 144 may be used as a pad. A fifth conductive layer (not shown) may be formed on the first plug, the second plug 144, and the fourth insulation layer 142. The fifth conductive layer may be the same as or different from the fourth conductive layer.

The fifth conductive layer may be patterned into a second upper wiring 146, i.e., a structure including the first plug and contacting the first upper wiring 132 in the cell array region, and a third upper wiring 148, i.e., a structure including the second plug 144 and contacting a contact region of the substrate 100 in the peripheral circuit region. The second upper wiring 146 may be electrically connected to the first upper wiring 132 in the cell array region, and the third upper wiring may make contact with the contact area of the substrate 100 via the second plug 144 in the peripheral circuit region. For example, the second upper wiring 146 may function as a plate line. Further, the second upper wiring 146 may extend in a direction substantially perpendicular to that of the bit line positioned on the first insulation layer 112, and thus may extend substantially parallel with the word line. According to another example embodiment, additional mask patterns may be formed on the second upper wiring 146 and the third upper wiring 148, thereby forming a second upper wiring structure including the second upper wiring 146 and the additional mask pattern in the cell array region of the substrate 100 and forming a third upper wiring structure including the third upper wiring 148 and the additional mask pattern in the peripheral circuit region.

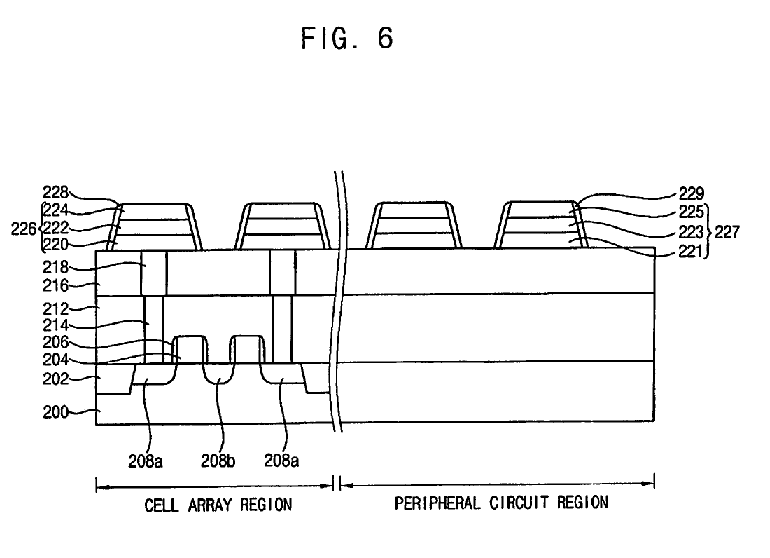

FIG. 6 illustrates a cross-sectional view of a method of manufacturing a semiconductor memory device according to another example embodiment. In FIG. 6, a device isolation layer 202, a lower structure, a first insulation layer 212, a first contact 214, a second insulation layer 216, and a second contact 218 may be formed on a substrate 200 by a substantially same process as described previously with reference to FIG. 1.

The lower structure, e.g., at least one transistor, may include a gate structure 204, a gate spacer 206, a first impurity region 208a, and a second impurity region 208b provided in a cell array region of the substrate 200 on which the device isolation layer 202 is formed. The first contact 214 may be connected to the first impurity region 208a through the first insulation layer 212. The second contact 218 may be connected to the first contact 214 through the second insulation layer 216 to be electrically connected to the first impurity region 208a.

Referring to FIG. 6, a lower electrode layer (not shown), a dielectric layer (not shown), and an upper electrode layer (not shown) may be sequentially formed on the second insulation layer 216 through which the second contact 218 may be formed. In an example embodiment, the lower electrode layer, the dielectric layer and the upper electrode layer may be formed on the entire surface of the substrate 200 including the cell array region and the peripheral circuit region.

The upper electrode layer, the dielectric layer, and the lower electrode layer may be sequentially patterned to form at least one capacitor 226 and at least one dummy structure 227 simultaneously on the second insulation layer 216. The capacitor 226 may be formed in the cell array region of the substrate 200, and the dummy structure 227 may be formed in the peripheral circuit region of the substrate 200. The capacitor 226 may include a lower electrode 220, a dielectric layer pattern 222, and an upper electrode 224. The dummy structure 227 may include a dummy lower electrode 221, a dummy dielectric layer pattern 223, and a dummy upper electrode 225.

In example embodiments, the lower electrode 220 may include a first lower electrode pattern and a second lower electrode pattern, and the upper electrode 224 may include a first upper electrode layer pattern and a second upper electrode layer pattern in substantially the same process as described previously with reference to capacitor 125 in FIG. 2. The dummy lower electrode 221 of the dummy structure 227 may have substantially the same multilayer structure as the lower electrode 220 of the capacitor 226, and the dummy upper electrode 225 of the dummy structure 227 may have substantially the same multilayer structure as the upper electrode 224 of the capacitor 226. For example, the dummy lower electrode 221 may include first and second dummy lower electrode layer patterns, and the dummy upper electrode 225 may include first and second dummy upper electrode layer patterns. The capacitor 226 and the dummy structure 227 may have a substantially same height, i.e., relative to a top surface of the second insulation layer 216.

A first blocking layer pattern 228 and a second blocking layer pattern 229 may be formed on a sidewall of the capacitor 226 and on a sidewall of the dummy structure 227, respectively. For example, a blocking layer (not shown) may be formed on the second insulation layer 216 on which the capacitor 226 and the dummy structure 227 are formed to a sufficient thickness to cover the capacitor 226 and the dummy structure 227. Then, the blocking layer may be patterned into the first blocking layer pattern 228 and the second blocking layer pattern 229. As a modification of the present example embodiment, the second blocking layer pattern 229 may be omitted from the sidewall of the dummy structure 227 by controlling processing conditions of the patterning process for forming the blocking layer patterns 228 and 229. No blocking layer patterns may be formed on the sidewalls of the capacitor 226 and the dummy structure 227, respectively, for simplification of the manufacturing process for a semiconductor device, as would be known to one of ordinary skill in the art.

Though not shown in FIG. 6, a third insulation layer (not shown) may be formed on the second insulation layer 216 to a sufficient thickness to cover the capacitor 226 and the dummy structure 227 by substantially the same process as described previously with reference to FIG. 2. Then, at least one upper wiring, which may be electrically connected to the upper electrode 224 of the capacitor 226, may be formed on the third insulation layer by substantially the same process as described with reference to FIG. 2.

According to example embodiments, the capacitor 226 and the dummy structure 227 may be formed on, e.g., directly on, the second insulation layer 126 by substantially the same process and may have substantially the same structure. Therefore, the capacitor 226 and the dummy structure 227 may have a substantially same height, i.e., as measured from the top surface of the second insulation layer 216. Thus, the third insulation layer, which may be formed on the second insulation layer to a sufficient thickness to cover the capacitor 226 and the dummy structure 227, may be formed uniformly along the cell array region and the peripheral circuit region of the substrate 102. Accordingly, the third insulation layer may have no density difference between the cell array region and the peripheral circuit region of the substrate 200. Thus, no cracks may be generated between the upper wiring and the upper electrode of the capacitor 226.

That is, the capacitor 226 and the dummy structure 227 may be simultaneously formed in the cell array region and the peripheral circuit region of the substrate 200, respectively, in the same process in such a manner that an upper surface of the capacitor 226 may be substantially coplanar with an upper surface of the dummy structure 227. Thus, the uniformity of the capacitor 226 and the dummy structure 227 may minimize the density difference in the third insulation layer between the cell array region and the peripheral circuit region of the substrate 200. Therefore, internal stress in the third insulation layer caused by the density difference between the cell array region and the peripheral circuit region may be sufficiently reduced in the third insulation layer. Accordingly, lifting failures between the upper wiring and the upper electrode 224 of the capacitor 226 may be prevented or substantially minimized by the internal stress reduction in the third insulation layer, thereby improving electrical characteristics and operational reliability of the semiconductor device including the capacitor 226.

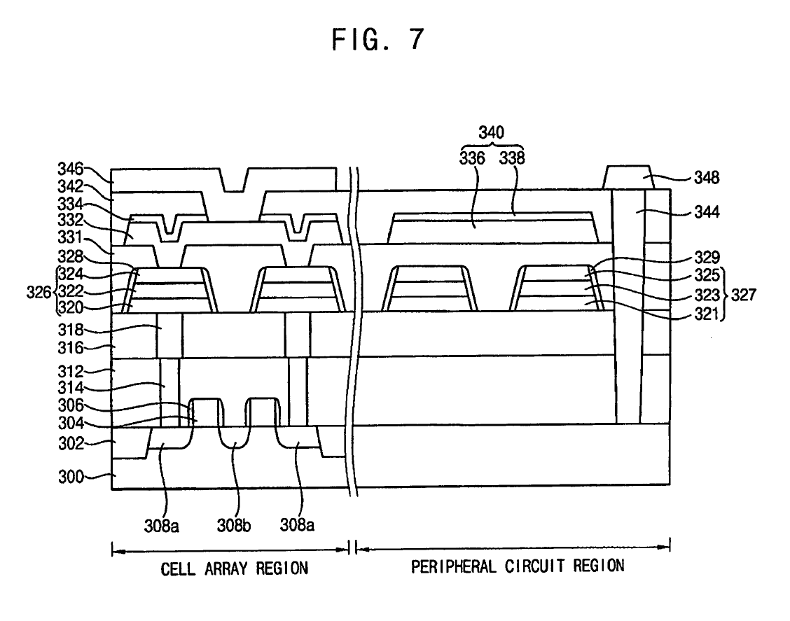

FIG. 7 illustrates a cross-sectional view of a method of manufacturing a semiconductor memory device according to another example embodiment. In FIG. 7, a device isolation layer 302, a lower structure, e.g., a transistor, a first insulation layer 312, a first contact 314, a second insulation layer 316, a third contact 318, a capacitor 326, and a first dummy structure 327 may be formed on a substrate 300 including first and second impurity regions 308a and 308b by substantially the same process as described with reference to FIG. 6. In FIG. 7, the capacitor 326 may include a lower electrode 320, a dielectric layer pattern 322, and an upper electrode 324, and the first dummy structure 327 may include a dummy lower electrode 321, a dummy dielectric layer pattern 323, and a dummy upper electrode 325 corresponding to the dummy structure 227 illustrated in FIG. 6. Here, the capacitor 326 and the first dummy structure 327 may have substantially the same structure and height. In addition, first second blocking layer patterns 328 and 329 may be provided on sidewalls of the capacitor 326 and the first dummy structure 327, respectively.

Referring to FIG. 7, a third insulation layer 331 sufficiently covering the capacitor 326 and the first dummy structure 327 may be formed on the second insulation layer 316. Then, the third insulation layer 331 may be partially etched to form a first opening (not shown) exposing the upper electrode 324 of the capacitor 326. The first dummy structure 327 in the peripheral circuit region of the substrate 300 may not exposed.

A first upper conductive layer may be formed on the third insulation layer 331 to a sufficient thickness to fill up the first opening and may include a metal and/or a metal compound. In an example embodiment, the first upper conductive layer may be formed on the third insulation layer 331 continuously along the cell array region and the peripheral circuit region of the substrate 300. That is, the first upper conductive layer may be continuously formed on both a first portion of the third insulation layer 331 in the cell array region and a second portion of the third insulation layer in the peripheral circuit region. The first upper conductive layer may have substantially the same structure and composition as the third conductive layer described with reference to FIG. 4.

A mask layer (not shown) may be formed on the first upper conductive layer. Then, the mask layer and the first upper conductive layer may be sequentially removed from the third insulation layer 331 to form a first upper wiring structure making contact with the capacitor 326 in the cell array region and a second dummy structure 340 on the third insulation layer 331 in the peripheral circuit region. In the present example embodiment, the first upper wiring structure may include a first upper wiring 332 and a mask pattern 334, and the second dummy structure 340 may include a dummy conductive pattern 336 and a dummy mask pattern 338. The second dummy structure 340 may be positioned over the first dummy structure 327, e.g., the second dummy structure 340 may completely overlap a plurality of the first dummy structures 327. The first upper wiring structure and the second dummy structure 340 may have different cross-sections, but may have a substantially same height as measured from the third insulation layer 331.

Referring again to FIG. 7, a fourth insulation layer 342 may be formed on the third insulation layer 331 to a sufficient thickness to cover the first upper wiring structure and the second dummy structure 340. Then, the fourth insulation layer 342 and the mask pattern 334 of the first upper wiring structure may be partially removed by an etching process in the cell array region of the substrate 300 to form an opening (not shown) exposing the first upper wiring 332 of the first upper wiring structure. The fourth insulation layer 342, the third insulation layer 331, the second insulation layer 316, and the first insulation layer 312 may be partially and sequentially etched in the peripheral circuit region to form a hole (not shown) exposing a contact area of the substrate 300.

A second upper conductive layer (not shown) may be formed on the fourth insulation layer 342 to a sufficient thickness to fill up the opening and the hole. In the present example embodiment, the second upper conductive layer may have substantially the same structure and composition as the fourth conductive layer described with reference to FIG. 5. The second upper conductive layer may be planarized to form a first plug (not shown) filling the opening and a second plug 344 filling the hole. The first plug may be dented but the second plug 344 may have a planar upper surface. The first plug may be used as a wiring, and the second plug 344 may be used as a pad. A third upper conductive layer may be formed on the first plug, the second plug 344, and the fourth insulation layer 342. The third upper conductive layer may be the same as or different from the second upper conductive layer. The third upper conductive layer may be patterned to form a second upper wiring 346 connected with the first plug in the cell array region and a third upper wiring 348 connected with the second plug 344 in the peripheral circuit region. The second upper wiring 346 and the first plug may be electrically connected to the first upper wiring 332 in the cell array region and the third upper wiring 348, and the second plug 344 may be electrically connected to the contact area of the substrate 300 in the peripheral circuit region. Though not shown in FIG. 7, mask patterns may be additionally formed on the second and third upper wirings 346 and 348, respectively, to form a second upper wiring structure and a third upper wiring structure in the cell array region and the peripheral circuit region, respectively, as would be known to one of ordinary skill in the art.

According to example embodiments, the first and the second dummy structures 327 and 340 may be formed in the peripheral circuit region of the substrate 300. Thus, the pattern on the substrate 300 may be sufficiently uniform along the cell array region and the peripheral circuit region. Particularly, the second dummy structure 340 on the third insulation layer 331 in the peripheral circuit region may sufficiently compensate for the density difference in the third insulation layer 331. Thus, the fourth insulation layer 342 may be uniformly formed on the third insulation layer 331 along the cell array region and the peripheral circuit region of the substrate 300. Therefore, the uniformity of the fourth insulation layer 342 may minimize the density difference in the fourth insulation layer 342 between the cell array region and the peripheral circuit region of the substrate 300 to sufficiently reduce internal stress in the fourth insulation layer 342 caused by the density difference thereof. Accordingly, cracks on a boundary surface of the capacitor 326 and the first upper wiring 332 (and/or the second upper wiring 346) may be sufficiently prevented by the stress reduction of the fourth insulation layer 342 to prevent lifting failures between the upper wirings 332 and 346 and the capacitor 326 and improve the electrical characteristics and the operational reliability of the semiconductor device including the capacitor 326.

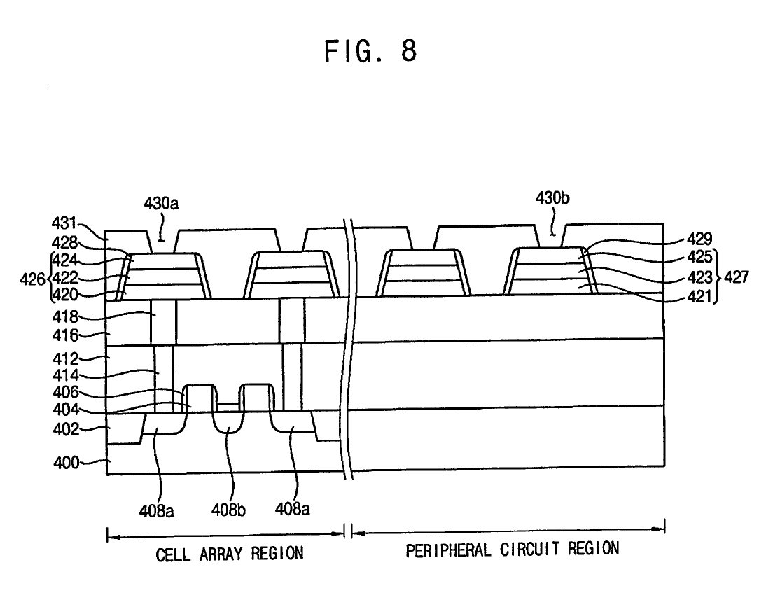

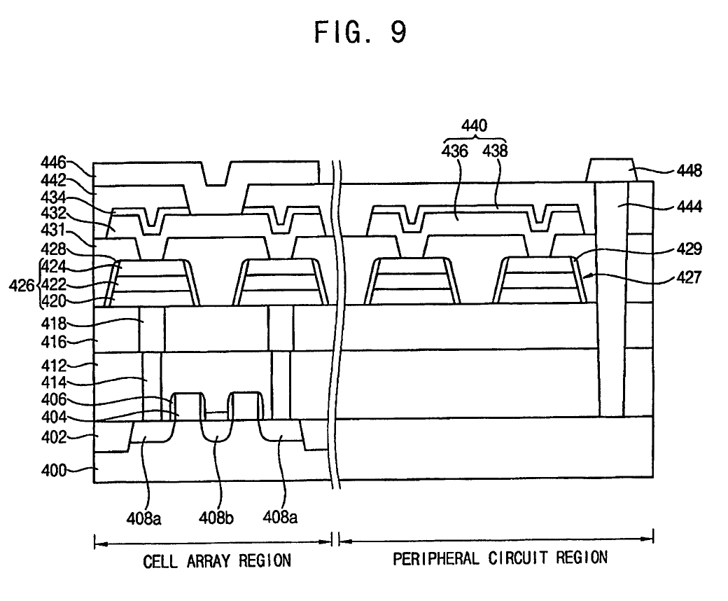

FIGS. 8 and 9 illustrate cross-sectional views of a method of manufacturing a semiconductor device according to other example embodiments. In FIGS. 8 and 9, a gate structure 404, a gate spacer 406, first and second impurity regions 408a and 408b, a first insulation layer 412, a first contact 414, a second insulation layer 416, a second contact 418, a capacitor 426, and a first dummy structure 427 may be formed on a substrate 400 including a device isolation layer 402 by substantially the same process as described with previously reference to FIG. 6. In FIG. 8, the capacitor 426 may include a lower electrode 420, a dielectric layer pattern 422, and an upper electrode 424, and the first dummy structure 427 may include a dummy lower electrode 421, a dummy dielectric layer pattern 423, and a dummy upper electrode 425. Further, first and second blocking layer patterns 428 and 429 may be formed on sidewalls of the capacitor 426 and the first dummy structure 427, respectively.

In example embodiments, the lower electrode 420 of the capacitor 426 may be formed as a double-layer structure including, e.g., titanium and platinum, and the dielectric layer pattern 422 may include, e.g., PZT. For example, a dielectric layer may be formed on the lower electrode 420 and then an annealing process may be performed to the dielectric layer at a temperature of about 650° C. to about 850° C. for about 30 seconds to about 120 seconds under an oxygen atmosphere. The upper electrode 424 may include, e.g., iridium oxide.

Referring to FIG. 8, a third insulation layer 431 may be formed on the second insulation layer 426 to a sufficient thickness to cover the capacitor 426 and the first dummy structure 427. The capacitor 426 may be formed in the cell array region of the substrate 400, and the first dummy structure 427 may be formed in the peripheral circuit region of the substrate 400. The third insulation layer 431 may be uniformly formed on the second insulation layer 416 across the cell array region and the peripheral circuit region of the substrate 400 because the first dummy structure 427 may be formed on the second insulation layer 416 in the peripheral circuit region corresponding to the capacitor 426 in the cell array region, thereby minimizing density difference in the third insulation layer 431 between the cell array region and the peripheral circuit region of the substrate 400.

Thereafter, the third insulation layer 431 may be partially etched to form a first opening 430a and a second opening 430b. The first opening 430a may expose the upper electrode 424 of the capacitor 426 in the cell array region of the substrate 400. The second opening 430b may expose the dummy upper electrode 425 of the first dummy structure 427 in the peripheral circuit region.

Referring to FIG. 9, a first upper conductive layer (not shown) may be formed on the third insulation layer 431 to a sufficient thickness to fill up the first and second openings 430a and 430b. That is, the first upper conductive layer may be formed on the entire substrate 400 across the cell array region and the peripheral circuit region.

A mask pattern 434 and a dummy mask pattern 438 may be formed on the first upper conductive layer. Then, the first upper conductive layer may be patterned to form a first upper wiring 432 connected to the upper electrode 424 in the cell array region, while forming a dummy conductive layer pattern 436 connected to the dummy upper electrode 425 in the peripheral circuit region. Accordingly, a second dummy structure 440 including the dummy conductive layer pattern 436 and the dummy mask pattern 438 may be formed on the first dummy structure 427. Meanwhile, a first upper wiring structure including the first upper wiring 432 and the mask pattern 434 may be formed on the capacitor 426.

According to example embodiments, the first upper wiring 432 may include a low electrical resistive metal material, e.g., tungsten (W). Particularly, a barrier metal layer (not shown) may be formed on inner sidewall and bottom of the first opening 430a, and the first upper wiring 432 may be formed on the third insulation layer 431 to a sufficient thickness to fill up the first opening 430a. Thus, the first upper wiring 432 may be enclosed by the first barrier metal layer in the first opening 430a. In the present example embodiment, the barrier metal layer may be formed into a double-layer structure including a adhesive layer (not shown) on the inner sidewall and bottom of the first opening 430a and a anti-diffusion layer (not shown) on the adhesive layer in the first opening 430a. For example, a titanium layer may be formed on the inner sidewall and the bottom of the first opening 430a to a thickness of about 20 nm as the adhesive layer and a titanium nitride layer may be formed on the adhesive layer to a thickness of about 50 nm as the anti-diffusion layer. The second dummy structure 440 may have substantially the same structure as the first upper wiring structure and may be located in the peripheral circuit region of the substrate 400. Thus, the dummy conductive layer pattern 436 of the second dummy structure 440 may include a dummy adhesive layer (not shown) along an inner sidewall and bottom of the second opening 430b and a dummy anti-diffusion layer on the dummy adhesive layer in the second opening 430b.

A fourth insulation layer 442 covering the mask pattern 434 and the dummy mask pattern 438 may be formed on the third insulation layer 431. The first and the second dummy structures 427 and 440 may be formed in the peripheral circuit region of the substrate 400 in the same process as described above, and thus the fourth insulation layer 442 may be formed uniform on the third insulation layer 431 across the cell array region and the peripheral circuit region of the substrate 400. Accordingly, the fourth insulation layer 442 may have a uniform density on the third insulation layer, to thereby have no density difference between the cell array region and the peripheral circuit region of the substrate 400.

The fourth insulation layer 442 and the mask pattern 434 in the cell array region may be etched to form a third opening (not shown) exposing the first upper wiring 432. The fourth insulation layer 442, the third insulation layer 431, the second insulation layer 418, and the first insulation layer 412 in the peripheral circuit region may be sequentially etched to form a fourth opening (not shown) exposing a contact area of the substrate 400.

A second upper conductive layer (not shown) filling the third and the fourth openings may be formed on the fourth insulation layer 442. The second upper conductive layer may be planarized to form a first plug (not shown) filling the third opening and a second plug 444 filling the fourth opening. The first plug may be dented, but the second plug 444 may have a planar upper surface. The first plug may be used as a wiring and the second plug 444 may be used as a pad. A fifth conductive layer may be formed on the first plug, the second plug 444, and the fourth insulation layer 442. The fifth conductive layer may be patterned to form a second upper wiring 446 and a third upper wiring 448 in the cell array region and the peripheral circuit region, respectively. The second upper wiring 446 and the first plug may be connected to the first upper wiring 432, and a third upper pattern 448 may be electrically connected to the contact through the second plug 444.

In an example embodiment, the first and the second dummy structures 427 and 440 may be formed into the same structures as the capacitor 426 and the first upper wiring structure, which may be formed in the cell array region of the substrate 400, in the peripheral circuit region of the substrate 400. Therefore, the pattern uniformity on the entire substrate 400 may be sufficiently improved and the density difference of the third and the fourth insulation layers 431 and 442 may be minimized between the cell array region and the peripheral circuit region of the substrate 400. Accordingly, internal stress within the third and fourth insulation layers 426 and 442 caused by the density difference thereof may be sufficiently reduced, and thus lifting failures of the first and the second upper wirings 432 and 446 from the upper electrode 424 of the capacitor 426 may be minimized or prevented. Contact reliability between the upper electrode 424 and the first upper wiring 432 and between the first upper wiring 432 and the second upper wiring 446 may be largely improved and the operational reliability and the electrical characteristics of the semiconductor device may be remarkably improved.

In a conventional semiconductor device, a dummy structure is not formed in the peripheral circuit region of a substrate, and thus patterns are formed only in the cell array region of the substrate, i.e., the patterns are not uniform across both the cell array region and the peripheral circuit region of the substrate. Therefore, an insulation layer formed on the patterns for electrically insulating the patterns from each other may be formed on the substrate to have a non-uniform density across the cell array region and the peripheral circuit region. Thus, the insulation layer may have a large density difference between the cell array region and the peripheral circuit region of the substrate. The large density difference of the insulation layer may cause great internal stress in the insulation layer, so cracks may be generated at a boundary surface between the capacitor and the upper wiring due to the internal stress of the insulation layer. Accordingly, the capacitor and the upper wiring may be lifted from each other by the cracks, thereby deteriorating electrical characteristics of the semiconductor device.

In the semiconductor device according to an example embodiment, however, the semiconductor device may include at least one dummy structure, i.e., a dummy pattern, in the peripheral circuit region of the substrate, so patterns having a substantially same height may be formed on an entire substrate uniformly across the cell array region and the peripheral circuit region, e.g., uniformly distributed. Thus, the insulation layer for electrically insulating the patterns from each other may be formed on the entire substrate uniformly. Therefore, the density difference of the insulation layer in the cell array region and the peripheral circuit region of the substrate may be minimized. Accordingly, the cracks may hardly be generated between the upper wiring and the upper electrode, thereby reducing lifting failures between the capacitor and the upper wiring in the semiconductor device. The electrical characteristics and the operational reliability of the semiconductor device may be largely improved.

According to example embodiments, a dummy capacitor pattern, which may have substantially the same structure as the capacitor in the cell array region, and/or a dummy pattern, which may have substantially the same structure as the conductive pattern in the cell array region, may be formed on the peripheral circuit region of the substrate. Thus, the pattern and the insulation layer for electrically insulating the pattern from each other may be formed on the substrate uniformly across the cell array region and the peripheral circuit region of the substrate. Therefore, the density difference of the insulation layer may be minimized between the cell array region and the peripheral circuit region of the substrate and internal stress in the insulation layer may be sufficiently reduced at a boundary region of the cell array and peripheral circuit regions. Further, a leakage current may also be largely reduced in the semiconductor memory device, and thus the data retention capability and polarization degree of the dielectric layer of the capacitor may be sufficiently maintained in the semiconductor device, to thereby sufficiently prevent deterioration of the data retention capability and the polarization degree of the dielectric layer in the semiconductor device.

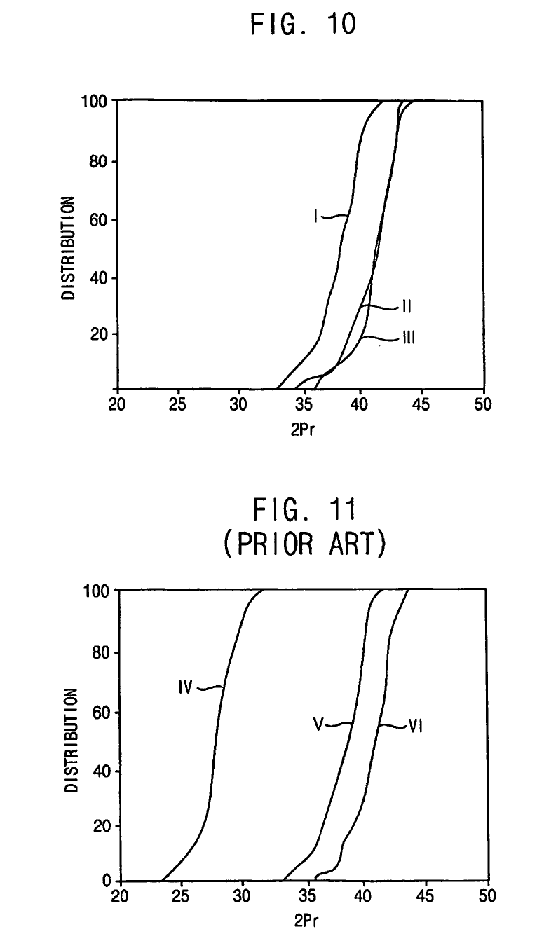

FIG. 10 illustrates a graph of a polarization degree distribution in a semiconductor device including a dummy structure formed in a peripheral circuit region in accordance with example embodiments. FIG. 11 illustrates a graph of a polarization degree distribution in a conventional semiconductor device not including a dummy structure in a peripheral circuit region.

In FIG. 10, each of Line I, Line II, and Line III indicates a respective distribution of 2Pr values which were measured at three arbitrary points in a semiconductor device in accordance with example embodiments. In contrast, in FIG. 11, each of Line IV, Line V, and Line VI indicates a respective distribution of 2Pr values which were measured at three arbitrary measuring points in a conventional semiconductor device.

Referring to FIG. 10, the measured 2Pr values in Lines I-III were in a relatively small range of about 33 μC/cm² to about 45 μC/cm², regardless of the position of the measuring points within the semiconductor device, i.e., the distribution of points in the semiconductor device was within the entire area of the semiconductor device. Thus, the graph in FIG. 10 illustrates that the polarization degree of the dielectric layer was uniformly distributed in the entire semiconductor device according to an example embodiment, regardless of the positioning of the measuring points, i.e., a difference between polarization degrees of the cell array region and the peripheral circuit region was insignificant. In contrast, as illustrated in FIG. 11, the 2Pr values measured in a conventional semiconductor device were in a relatively large range of about 23 μC/cm² to about 50 μC/cm². Thus, the graph in FIG. 11 illustrates that the polarization degree of the dielectric layer was widely and non-uniformly distributed in the conventional semiconductor device.

The above non-uniform distribution of the polarization degree i.e., in FIG. 11, is believed to be caused by current leakage due to lifting failures between the upper wiring and the capacitor in the conventional semiconductor device. The current leakage was generated at various points in the conventional semiconductor device, and the measured 2Pr values were significantly varied in accordance with the leakage current. Thus, the polarization degree distribution in the conventional semiconductor device was much more non-uniform than the polarization degree in the semiconductor device according to an example embodiment. In contrast, the measured 2Pr values were varied in a small range and substantially uniform across the various measuring points in the semiconductor device according to an example embodiment. Thus, the polarization degree distribution and the data retention capability may be substantially improved in the semiconductor device according to an example embodiment due to the dummy pattern in the peripheral circuit region of the substrate.

According to example embodiments, at least one dummy structure may be formed in a peripheral circuit region of a substrate in such a configuration that an upper portion of a dummy structure may have substantially the same height as that of a capacitor and/or an upper wiring structure in a cell array region of the substrate. Thus, a pattern on the substrate may be formed to be uniform on the entire substrate across the cell array region and the peripheral circuit region of the substrate. Therefore, first and/or second insulation layers with which the patterns are covered and by which the patterns are electrically insulated from each other may also be formed to be uniform, so that a density difference of the first and/or second insulation layers may be minimized between the cell array region and the peripheral circuit region. Accordingly, internal stress of the insulation layer may be minimized in a boundary region of the cell array region and the peripheral circuit region, to thereby prevent cracks in a boundary region of the upper wiring structure and the capacitor. The prevention of the cracks may sufficiently minimize lifting failures between the upper wiring structure and the capacitor in a semiconductor device, to thereby improve the electrical characteristics and operational reliability of the semiconductor device including the upper wiring structure and the dummy structure.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a substrate including a cell array region and a peripheral circuit region;
a lower structure on the substrate in the cell array region;
a first insulation layer on the substrate across the cell array region and the peripheral circuit region, the lower structure being covered with the first insulation layer;
a capacitor on the first insulation layer in the cell array region of the substrate, the capacitor including a lower electrode, a dielectric layer pattern, and an upper electrode;
a second insulation layer on the first insulation layer, the capacitor being covered with the second insulation layer;
a first upper wiring structure on the second insulation layer, the first upper wiring structure being electrically connected to the capacitor and including an upper wiring and a mask pattern; and
at least one dummy structure positioned in the peripheral circuit region of the substrate.

2. The semiconductor device as claimed in claim 1, wherein the dummy structure is positioned on the first insulation layer and has a substantially same structure as the capacitor.

3. The semiconductor device as claimed in claim 2, wherein the dummy structure includes a dummy lower electrode, a dummy dielectric layer pattern, and a dummy upper electrode.

4. The semiconductor device as claimed in claim 2, further comprising a blocking layer pattern on a sidewall of at least one of the capacitor and the dummy structure.

5. The semiconductor device as claimed in claim 2, wherein the dummy structure and the capacitor extend to a substantially same height with respect to the first insulation layer.

6. The semiconductor device as claimed in claim 2, further comprising a second dummy structure on the second insulation layer, the second dummy structure having a substantially same height as the first upper wiring structure.

7. The semiconductor device as claimed in claim 6, wherein the second dummy structure contacts the first dummy structure.

8. The semiconductor device as claimed in claim 1, wherein the dummy structure is positioned on the second insulation layer and extends to a substantially same height as the first upper wiring structure.

9. The semiconductor device as claimed in claim 8, wherein the dummy structure includes a dummy conductive layer pattern and a dummy mask pattern.

10. The semiconductor device as claimed in claim 1, wherein the dummy structure is on the first insulation layer, an upper surface of the dummy structure being substantially level with an upper surface of the capacitor or with an upper surface of the first upper wiring structure, upper surfaces of the dummy structure, capacitor, and first upper wiring structure facing away from the substrate.

11. The semiconductor device as claimed in claim 1, further comprising:
a third insulation layer covering the first upper wiring structure; and
a second upper wiring structure positioned on the third insulation layer and electrically connected to the first upper wiring structure.

12. A method of manufacturing a semiconductor device, comprising:
forming a lower structure in a cell array region of a substrate, the substrate including the cell array region and a peripheral circuit region;
forming a first insulation layer on the substrate across the cell array region and the peripheral circuit region, so that the lower structure in the cell array region is covered with the first insulation layer;
forming a capacitor on the first insulation layer in the cell array region of the substrate;
forming a second insulation layer on the first insulation layer, so that the capacitor is covered with the second insulation layer, the capacitor including a lower electrode, a dielectric layer pattern, and an upper electrode;
forming a first upper wiring structure on the second insulation layer, the first upper wiring structure being electrically connected to the capacitor and including an upper wiring and a mask pattern; and
forming at least one dummy structure in the peripheral circuit region of the substrate.

13. The method as claimed in claim 12, further comprising forming a blocking layer pattern on a sidewall of the capacitor.

14. The method as claimed in claim 12, wherein forming the first upper wiring structure and the dummy structure are performed simultaneously and include:
forming a conductive layer on the second insulation layer in the cell array region and the peripheral circuit region;
forming simultaneously a mask pattern on a portion of the conductive layer in the cell array region and a dummy mask pattern on a portion of the conductive layer in the peripheral circuit region; and
etching the conductive layer to form the upper first conductive layer pattern under the mask pattern and the dummy conductive layer pattern under the dummy mask pattern.

15. The method as claimed in claim 12, wherein forming the capacitor and the dummy structure are performed simultaneously and include:
forming a lower electrode layer on the first insulation layer in the cell array region and the peripheral circuit region;
forming a dielectric layer on the lower electrode layer;
forming an upper electrode layer on the dielectric layer; and
patterning simultaneously the upper electrode layer, the dielectric layer, and the lower electrode layer to form the capacitor in the cell array region, and a dummy structure in the peripheral circuit region, the dummy structure including a dummy lower electrode, a dummy dielectric layer pattern, and a dummy upper electrode.

16. The method as claimed in claim 15, further comprising forming a blocking layer pattern on a sidewall of each of the capacitor and the dummy structure.

17. The method as claimed in claim 15, further comprising:
forming a conductive layer on the second insulation layer in the cell array region and the peripheral circuit region;
forming a mask layer on the conductive layer; and
patterning the mask layer and the conductive layer to form the first upper wiring structure in the cell array region, and a second dummy structure including a dummy conductive pattern and a dummy mask pattern in the peripheral circuit region.

18. The method as claimed in claim 12, further comprising:
forming a third insulation layer on the second insulation layer, such that the first upper wiring structure is covered with the third insulation layer; and
forming a second upper wiring structure on the third insulation layer, such that the second upper wiring structure is electrically connected to the first upper wiring structure.

19. The method as claimed in claim 12, wherein the at least one dummy structure is formed simultaneously in a substantially same process as the capacitor or the first upper wiring structure.

20. The method as claimed in claim 19, wherein the dummy structure is formed to extend to a substantially same height as the capacitor or the first upper wiring structure.
